(19) United States
(12) Patent Application Publication
(10) Pub. No.: US 2025/0377242 A1
(43) Pub. Date: Dec. 11, 2025

(54) Laser Array Excitation and Multichannel Detection in a Spectrometer

(71) Applicant: Metrohm Spectro, Inc. (d/b/a Metrohm Raman), Plainsboro, NJ (US)

(72) Inventors: Keith T Carron, Centennial, WY (US); Garrick Tolman, Laramie, WY (US); Ben Morgan, Laramie, WY (US); Corbin Haugen, Laramie, WY (US)

(73) Assignee: Metrohm Spectro, Inc. (d/b/a Metrohm Raman), Plainsboro, NJ (US)

(21) Appl. No.: 19/107,837

(22) PCT Filed: Aug. 28, 2023
(86) PCT No.: PCT/US2023/031314

§ 371 Date: Feb. 28, 2025

Related U.S. Application Data
(60) Provisional application No. 63/401,709, filed on Aug. 28, 2022.
(60) Provisional application No. 63/404,975, filed on Sep. 9, 2022.

(51) Int. Cl. G01J 3/10; G01J 3/02; H01S 5/42

(52) U.S. Cl. CPC G01J 3/10; G01J 3/0208; G01J 3/0294; G01J 2003/102; H01S 5/423

(57) ABSTRACT

Spectrometers are provided comprising a plurality of excitation light sources (e.g., a plurality of laser light sources), a plurality of detector elements, and/or a plurality of excitation light sources and a plurality of detector elements. In one embodiment, for example, a spectrometer includes a light source adapted to provide an excitation incident beam, a detector adapted to detect a spectroscopy signal; and an optical system adapted to direct the excitation incident beam toward a sample, receive a spectroscopy signal from the sample and provide the spectroscopy signal to the detector. The light source includes a plurality of laser sources adapted to provide a plurality of excitation incident beams through the optical system and/or the detector comprises a plurality of detector elements.

### CROSS-REFERENCE TO RELATED APPLICATIONS

This application claims the benefit of U.S. provisional application No. 63/401,709, entitled “Laser Array Excitation and Multichannel Detection” and filed 28 Aug. 2022 and U.S. provisional application No. 63/404,975, entitled “Laser Array Excitation and Multichannel Detection” and filed 9 Sep. 2022, each application of which is hereby incorporated by reference as though fully set forth herein.

### BACKGROUND

### Field

This disclosure relates to a spectrometer using a laser array for excitation and/or a multichannel detection.

### Background

Typical raster systems of spectrometers move an excitation beam over a surface of a sample via a moving part. The raster systems move the excitation beam across an area of the sample within a single acquisition and averaging over a surface rather than producing discrete spectra.

### BRIEF SUMMARY

Spectrometers are provided comprising a plurality of excitation light sources (e.g., a plurality of laser light sources), a plurality of detector elements, and/or a plurality of excitation light sources and a plurality of detector elements. In one embodiment, for example, a spectrometer includes a light source adapted to provide an excitation incident beam, a detector adapted to detect a spectroscopy signal; and an optical system adapted to direct the excitation incident beam toward a sample, receive a spectroscopy signal from the sample and provide the spectroscopy signal to the detector. The light source includes a plurality of laser sources adapted to provide a plurality of excitation incident beams through the optical system and/or the detector comprises a plurality of detector elements.

In another embodiment, a spectrometer comprises a light source adapted to provide an excitation incident beam and a detector adapted to detect a spectroscopy signal. An optical system is adapted to direct the excitation incident beam toward a sample, receive a spectroscopy signal from the sample and provide the spectroscopy signal to the detector. The optical system comprises a beam expander adapted to expand the excitation incident beam.

The foregoing and other aspects, features, details, utilities, and advantages of the present invention will be apparent from reading the following description and claims, and from reviewing the accompanying drawings.

### BRIEF DESCRIPTION OF THE DRAWINGS

FIG. 1 shows an embodiment of an optical system of a spectrometer, such as but not limited to a Raman spectrometer.

FIG. 2 shows an example laser array used to provide a plurality of excitation beams.

FIG. 3 shows examples of laser excitation of a sample from an array excitation laser light source.

FIG. 4 shows an example of fitting a circle to a known line on a two-dimensional spectrometer detector.

FIGS. 5A and 5B show an embodiment of a spectrometer comprising a two-dimensional detector.

FIG. 6 shows an example of a curvature (aberration) (top) and a corrected, linearized image (bottom).

FIG. 7 shows an example of a detector composed of pixels with a specific well depth and an example of a digital readout in which an overflow comprises values greater than the pixel well depth leading to an aberration.

FIG. 8 shows an example embodiment of a method to produce a flattened optical image of a detector used to produce a digital readout of the detector pixels without overflow of the pixel well depth.

FIG. 9 shows an embodiment of a spectrometer in which a diode laser array is used to excite a sample and a two-dimensional (2-D) detector array is also used.

FIG. 10 shows examples of difficult samples to image using Raman spectroscopy.

FIG. 11 shows an example of a system and method adapted to detect one or more target within a complex sample.

FIG. 12 shows an embodiment of a spectrometer in which Raman collection is obtained with a 2-dimensional array.

FIG. 13 illustrates the Raman collection that is possible with a laser array. With this possibility the sample may be illuminated in a relatively large area while collecting from a relatively small area that is a subset of the illuminated area.

FIG. 14 shows another embodiment in which a standoff excitation is provided.

FIG. 15 shows a method of automatically triggering a sample in a fixed focus standoff spectrometer (e.g., Raman spectrometer).

FIGS. 16 and 17 include diagrams of an example spectrometer and of the spectrometer in use.

FIG. 18 is an illustration of an embodiment of optics for a laser array (e.g., VCSEL or diode laser array) imaging onto a 2-D array detector.

FIG. 19 illustrates an embodiment of a Raman spectrometer system comprising a combination of a laser array and a 2-D detector.

FIG. 20 shows an example of a spectroscopy collection using an addressable two-dimensional laser array and an addressable two-dimensional array detector.

FIG. 21 shows another example of a spectroscopy collection method using an addressable 2-D laser array and an addressable 2-D array detector.

FIG. 22 shows another example of a spectroscopy collection method using an addressable 2-D laser array and an addressable 2-D array detector.

FIG. 23 shows an example of fluorescence removal through BDM (Background decomposition method).

FIGS. 24 through 27 show example spectroscopy signals.

FIG. 28 illustrates the origin of the fluorescence in a Raman spectrometer application.

FIG. 29 shows an example spectroscopy signal.

FIG. 30 shows an illustration of operations of a Hadamard transformation.

### DETAILED DESCRIPTION

The following description is provided as an enabling teaching of the invention in its best, currently known embodiment. To this end, those skilled in the relevant art will recognize and appreciate that many changes can be made to the various aspects of the invention described herein, while still obtaining the beneficial results of the present invention. It will also be apparent that some of the desired benefits of the present invention can be obtained by selecting some of the features of the present invention without utilizing other features. Accordingly, those who work in the art will recognize that many modifications and adaptations to the present invention are possible and can even be desirable in certain circumstances and are a part of the present invention. Thus, the following description is provided as illustrative of the principles of the present invention and not in limitation thereof.

As used throughout, the singular forms “a,” “an” and “the” include plural referents unless the context clearly dictates otherwise. Thus, for example, reference to “a” component can include two or more such components unless the context indicates otherwise. Also, the words “proximal” and “distal” are used to describe items or portions of items that are situated closer to and away from, respectively, a user or operator such as a surgeon. Thus, for example, the tip or free end of a device may be referred to as the distal end, whereas the generally opposing end or handle may be referred to as the proximal end.

All directional references (e.g., upper, lower, upward, downward, left, right, leftward, rightward, top, bottom, above, below, vertical, horizontal, clockwise, and counterclockwise) are only used for identification purposes to aid the reader's understanding of the present invention, and do not create limitations, particularly as to the position, orientation, or use of the invention. Joinder references (e.g., attached, coupled, connected, and the like) are to be construed broadly and may include intermediate members between a connection of elements and relative movement between elements. As such, joinder references do not necessarily infer that two elements are directly connected and in fixed relation to each other.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

As used herein, the terms “optional” or “optionally” mean that the subsequently described event or circumstance may or may not occur, and that the description includes instances where said event or circumstance occurs and instances where it does not.

The term “substantially” as used herein may be applied to modify any quantitative representation which could permissibly vary without resulting in a change in the basic function to which it is related.

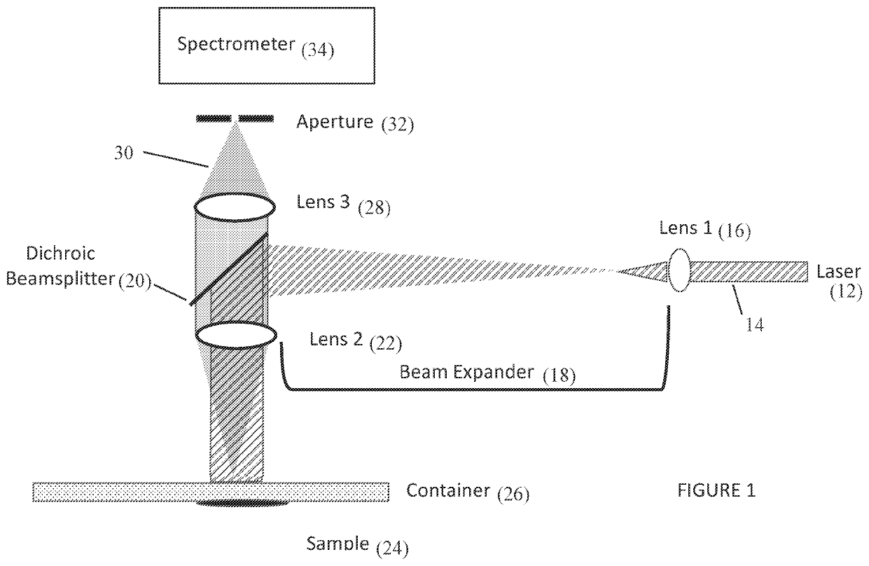

FIG. 1 shows an embodiment of an optical system of a spectrometer, such as but not limited to a Raman spectrometer 10. In this embodiment, an excitation light source 12 (e.g., laser) provides an excitation beam 14. The excitation beam is directed through a lens (lens 1) 16 and a beam expander 18 to a beam splitter 20 (e.g., dichroic beam splitter mirror). The beam splitter 20 directs the excitation beam 14 through a focusing lens (lens 2) 22 onto a sample 24. In this embodiment, the sample is disposed within a container 26 or behind a layer, such as a plastic bottle or layer.

A spectroscopy signal 30 generated at the sample from the excitation beam is directed at least in part back to the focusing lens (lens 2) 22 and is directed through the beam splitter 20 toward another focusing lens (lens 3) 28 that focuses the spectroscopy signal 30 on an aperture 32 through which the spectroscopy signal that passes is received by a spectrometer 34 for analysis.

In one embodiment, the intensity of Raman scattering from a material behind a translucent barrier, such as a container, may be increased. One method is to excite the sample over an area larger than the collection area. This is possible by a beam expander created by Lens 1 16 and Lens 2 22. This combination will create a large, expanded laser illumination on the container. Lens 2 22 of the beam expander can also act as the collection lens for Raman scattering produced as a result of the excitation of the sample 24. When focused a distance equivalent to the focal length of Lens 2 22 away from the sample it will produce a collimated beam that passes through the dichroic beamsplitter to Lens 3 28 which focus the small sampling area on to an aperture 32 of the spectrometer 34. The aperture 32 also acts as a spatial filter to eliminate off-axis radiation from the sample to enter the spectrometer 34.

The Raman in this example is proportional to the intensity (watts/area), and this method decreases the intensity of the laser when it is expanded and produces low Raman signals or requires a relatively more intense laser than a laser used in a system on which the excitation signal is tightly focused on a sample. The expanded excitation laser signal also reduces a laser hazard and can be used to provide an eye-safe standoff laser. Another method is to use an array of lasers to produce a relatively large excitation area relative to a collection area.

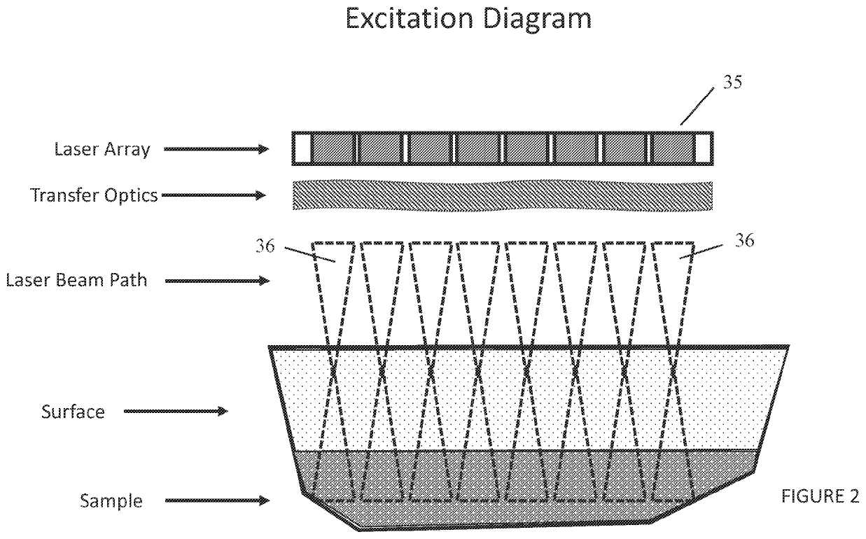

FIG. 2 shows an example laser array 35 used to provide a plurality of excitation beams 36. Each of the plurality of excitation beams is directed through transfer optics and through a surface to a sample 38. As shown in FIG. 2, each of the plurality of excitation beams 36 is directed by the transfer optics (optical system) toward a surface of the sample such that the plurality of excitation beams are dispersed across the surface of the sample. Where the target material is under a surface (e.g., a container such as a glass or plastic container), the plurality of excitation beams can extend through the surface to the underlying target material (e.g., a target particle) at a plurality of locations across the surface.

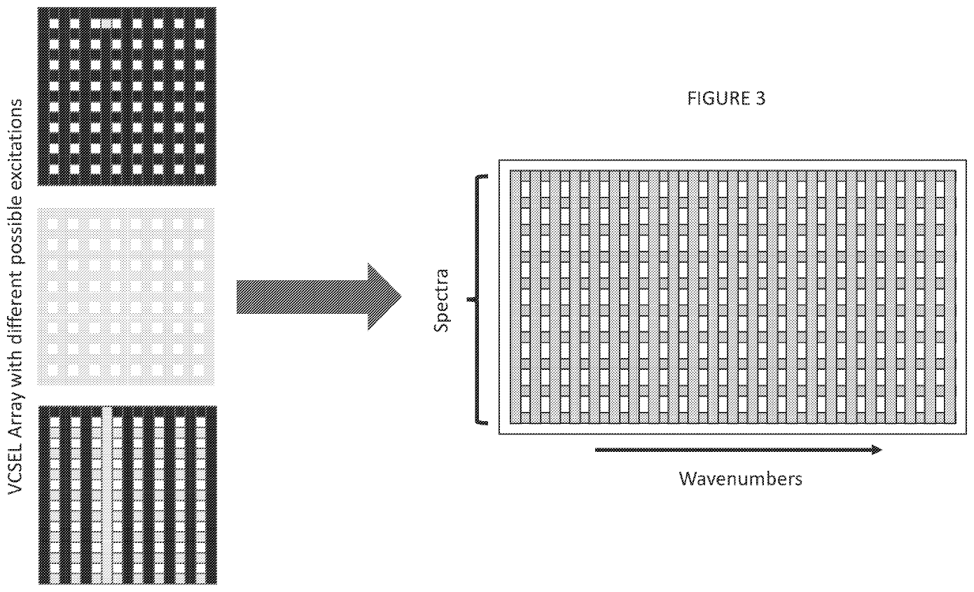

FIG. 3 shows examples of laser excitation of a sample from an array excitation laser light source. In one example, shown in the top array configuration, only a single laser of a laser array is turned on. In another example, shown in the middle array configuration, every laser of the array is turned on and the spectrometer detects both the light from the surface (aligned with the aperture) and sub surface light scattered from lasers not aligned with the aperture. In yet another example, shown in the bottom array configuration, combinations of laser excitation and detection are shown. In the bottom array configuration case, a spectrometer can collect a spectroscopy signal with the laser on spatially coinciding with excitation areas and with lasers also illuminating the sample spatially offset from the collection area.

In one embodiment, for example, a straight slit aperture can cause conical diffraction off the grating due to the change in diffraction angle with incident light angle on the grating. Vertically off-axis light will diffract at a lower angle than on-axis light. This cone is projected onto the imager and results in a curved image. One method to correct for this curvature is to use a curved slit aperture.

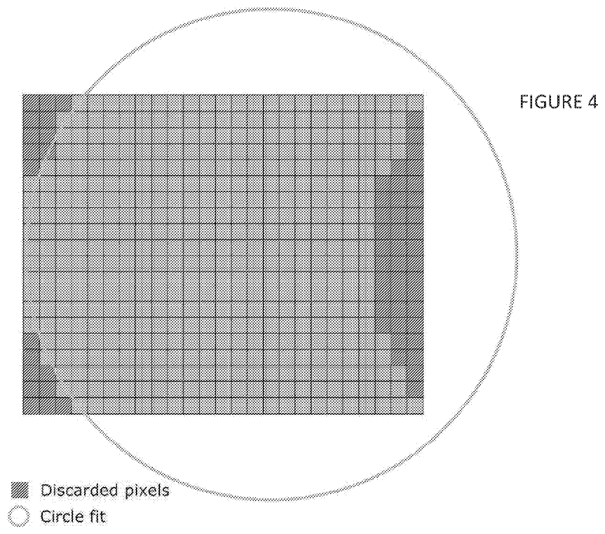

With a 2D sensor, the curvature can be corrected in software post-processing by fitting a circle to a known line and using the radius to adjust the alignment of each row of pixels with respect to the other rows. FIG. 4 shows an example of fitting a circle to a known line.

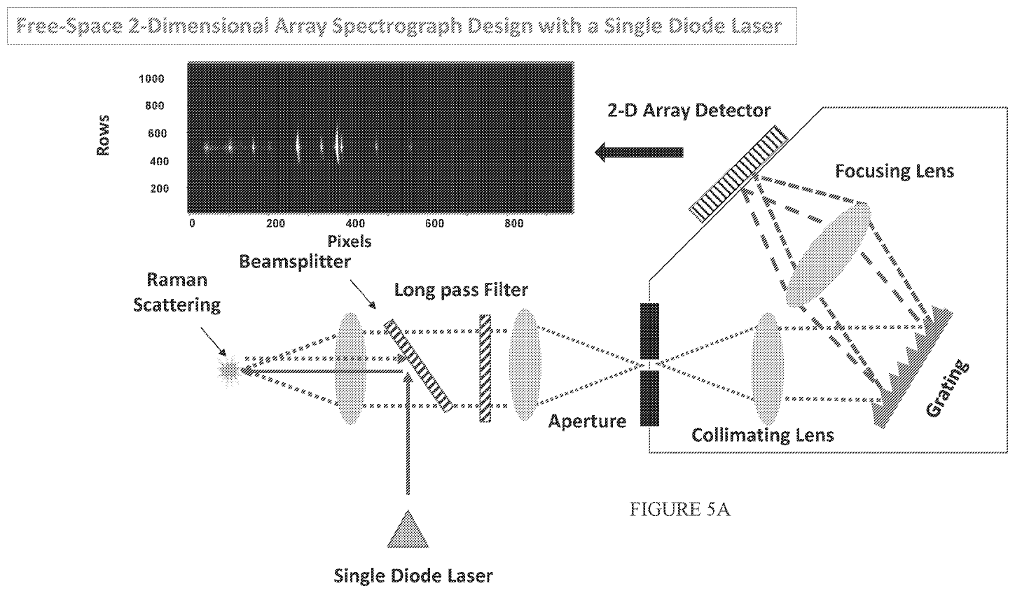

FIGS. 5A and 5B show an embodiment of a spectrometer comprising a two-dimensional detector. In this embodiment, the detector collects Raman in columns that can be binned. In FIG. 5A, the spectrograph design can create curved Raman images that do not average (bin) well along the columns. In FIG. 5B, the Raman signal has been linearized digitally and is able to be averaged (binned) properly along the columns.

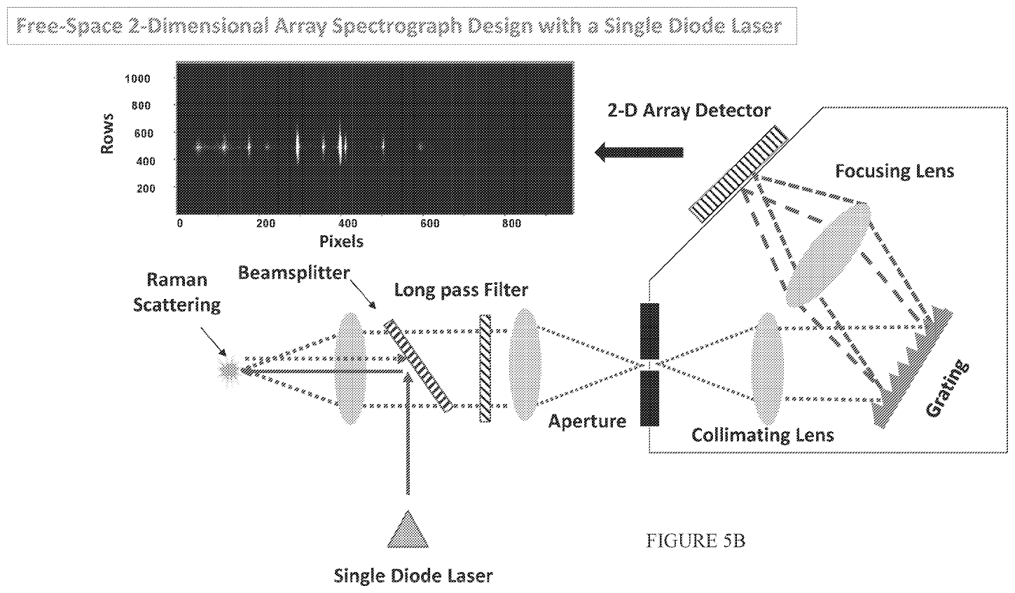

FIG. 6 shows an example of a curvature (aberration) (top) and a corrected, linearized image (bottom).

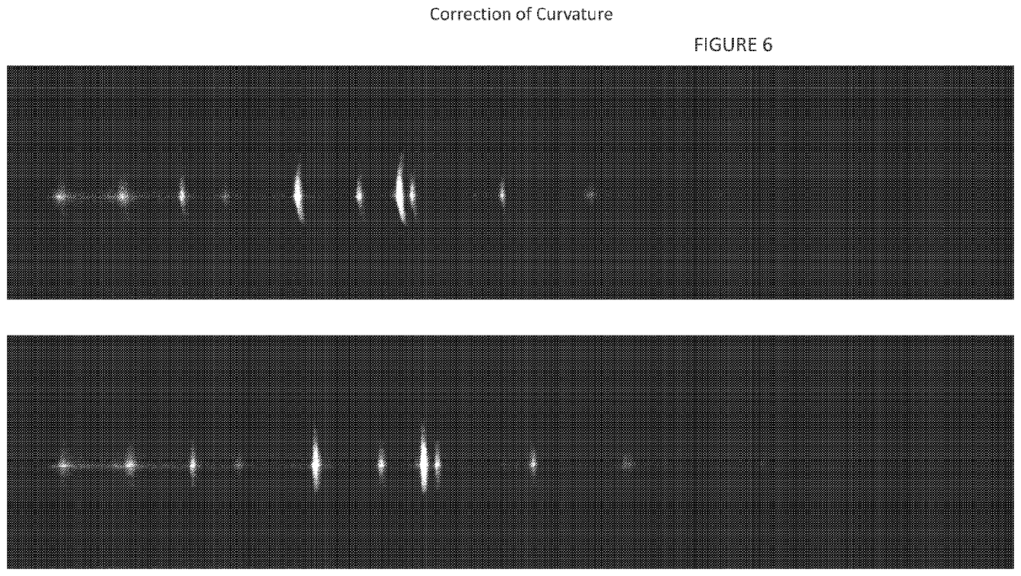

FIG. 7 shows an example of a detector composed of pixels with a specific well depth and an example of a digital readout in which an overflow comprises values greater than the pixel well depth leading to an aberration.

FIG. 7 results in a digital intensity profile that is not accurate due to overflowing. If the digital intensity were to be determined by binning (adding) the intensities, the resultant value would not correlate to the input signal.

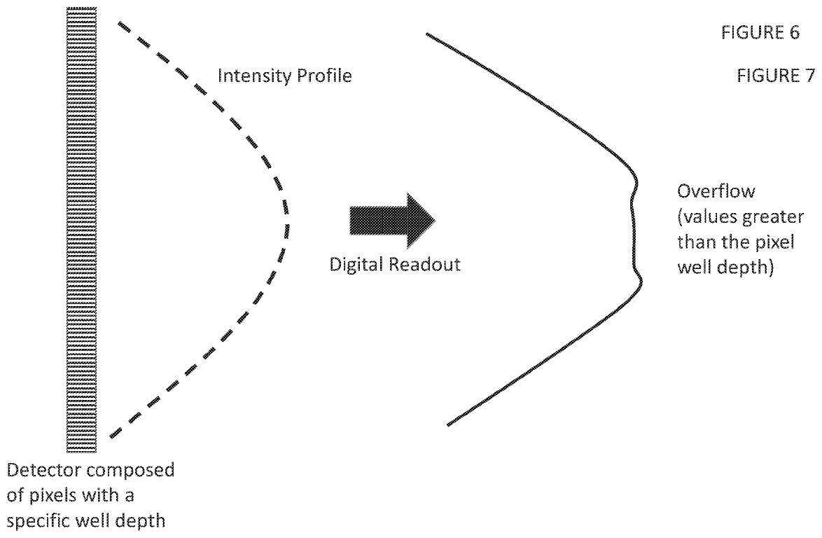

FIG. 8 shows an example embodiment of a method to produce a flattened optical image of a detector used to produce a digital readout of the detector pixels without overflow of the pixel well depth.

In FIG. 8, by flattening the input optically with a negative (concave) cylindrical lens, the intensity is spread across the pixels and eliminate overflows. Now when the digital signal is binned it is proportional to the incoming radiation signal.

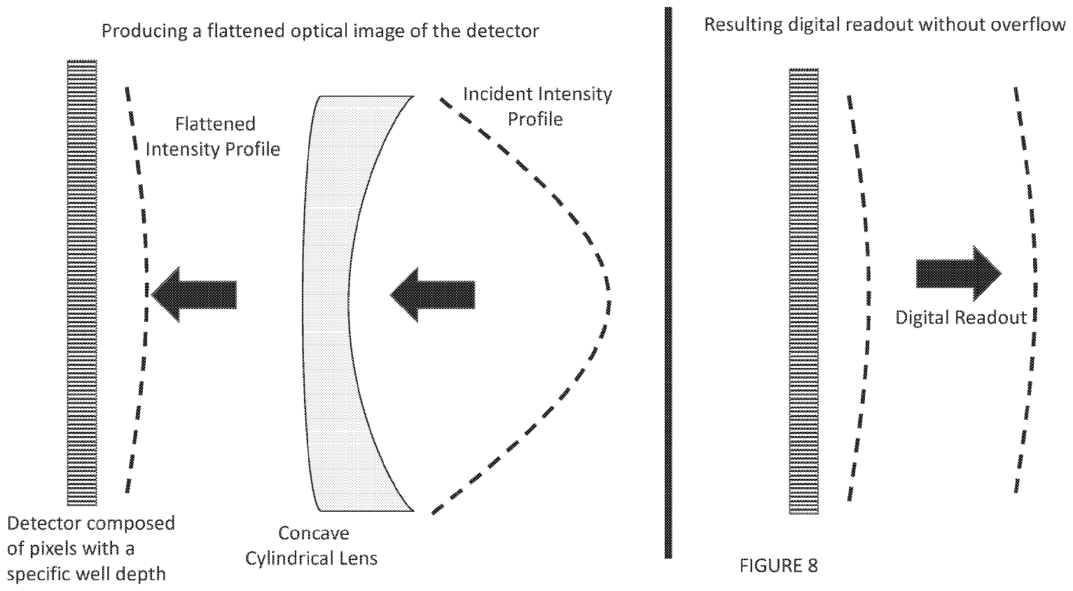

FIG. 9 shows an embodiment of a spectrometer in which a diode laser array is used to excite a sample and a two-dimensional (2-D) detector array is also used. In this example, a sample is inhomogeneous with only 2 particles of interest and a surface that also contributes signal. Signals from the pure substrate and sample mixed with spectral features from the substrate can be mathematically separated into a pure sample spectrum.

FIG. 9 shows a diagram of a spectrometer device comprising a two-dimensional (2D) diode laser array and a two-dimensional (2D) array detector. In this embodiment, the spectrometer is adapted to detect a target sample of an inhomogeneous sample. In this example, the inhomogeneous sample comprises a plurality of target materials disposes on a surface. Without a large sample area, the spectrometer may only detect the surface or a combination of the surface and a target. Even with a large area illumination, the spectrum will be a convolution of the surface spectrum and target spectrum. With a diode laser array and a multichannel detector, a discrete spectrum of the surface and the target can be observed. Algorithms can be used to separate the spectra to accurately identify the target material.

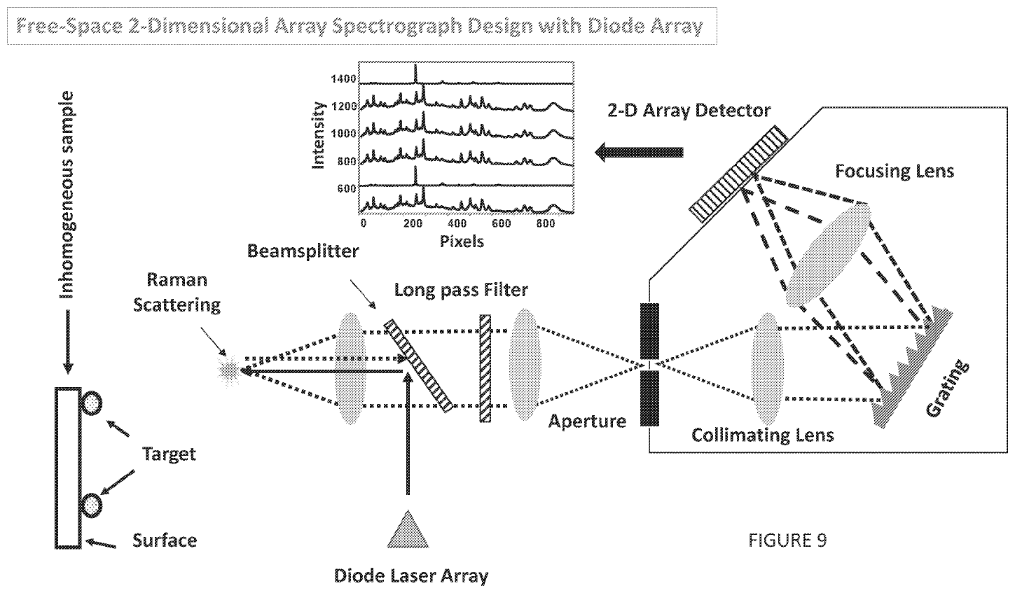

FIG. 10 shows examples of difficult samples to image using Raman spectroscopy. In the first example shown on the left, a field sample has crevices or cracks that contain a sample target, but in the spectrum the surface material interferes. In the second example shown on the left, the sample comprises a plurality of target sample particles disposed along a surface material in an inhomogeneous manner as described above with respect to FIG. 9. In various embodiments, a spectrometer is adapted to separate the signals of the surface from the target.

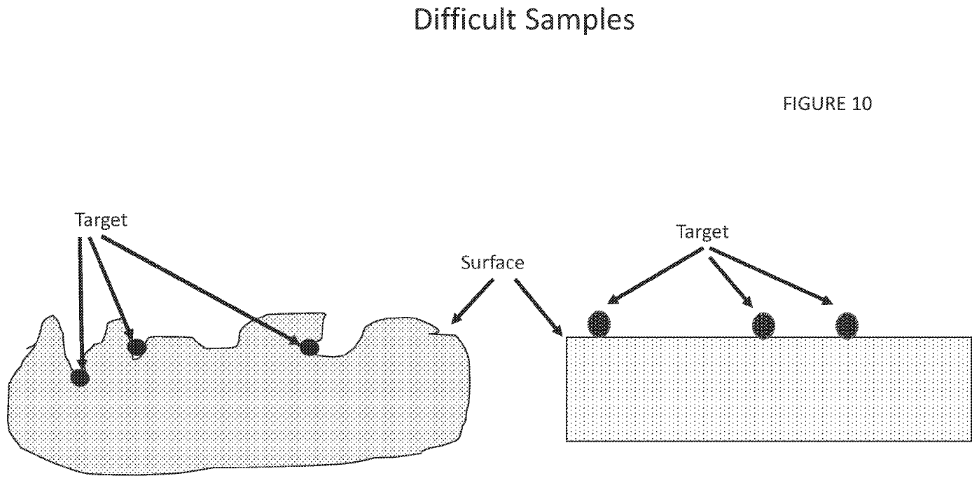

FIG. 11 shows an example of a system and method adapted to detect one or more target within a complex sample. FIG. 11 illustrates the concept of laser arrays coupled with a two-dimensional detector. Spectra of the targets and the surface are distinguishable and can be separated as discrete spectra on the 2-dimensional array.

In the embodiment shown in FIG. 11, for example, a vertical cavity surface-emitting laser (VCSEL) array provides a plurality of excitation light signals. Each of the excitation light signals pass through a beam splitter (e.g., a dichroic beam splitter) and are focused onto a portion of a complex sample via a collection lens as shown. A plurality of spectroscopy signals (e.g., Raman excitation signals) are returned to the collection lens and collimated toward the beam splitter. The spectroscopy signals are reflected by the beam splitter onto a two-dimensional (2D) detector (e.g., a multiple CMOS 2D detection array).

FIG. 11 also illustrates the laser array and two-dimensional detector's ability to produce a unique, discrete spectrum for each laser position (spatially separated on the surface). This is an advantage over methods that raster over the area and produce an average of surface and target spectra.

The laser array also produces a large array excitation and detection without moving parts. Current raster systems move the beam over the surface with a moving part and raster the whole area within a single acquisition, thus averaging over a surface rather than producing discrete spectra. Currently raster patterns are circular, an individually addressable laser array could produce any pattern shape.

FIG. 11 also shows a CMOS detector array. In one embodiment, the CMOS detector array can be used with an FPGA to rapidly collect the whole spectrum and transfer it to memory. Use processing from an FPGA (Field Programmable Gate Array) to perform math on the device rather than send raw data to a processor that performs math provides a speed gain.

DSERS. Dynamic Surface Enhanced Raman Spectroscopy (DSERS) is described in B. L. Scott and K. T. Carron, “Dynamic Surface Enhanced Raman Spectroscopy (SERS): Extracting SERS from Normal Raman Scattering,” Anal. Chem. 2012, 84, 8448-8451, which is incorporated by reference as if fully set forth herein. The DSERS concept has always suffered from the time required to acquire data from a CCD, read out the data, and store the data.

CMOS cameras are video devices with very high read rates. Using CMOS or similar detectors provides the ability to view smaller particles in a stream (Microfluidics) or static fluid (Brownian motion). Typically, the smaller the particle the faster it moves and that requires the instrument to have a fast read rate. A CMOS detector can improve that.

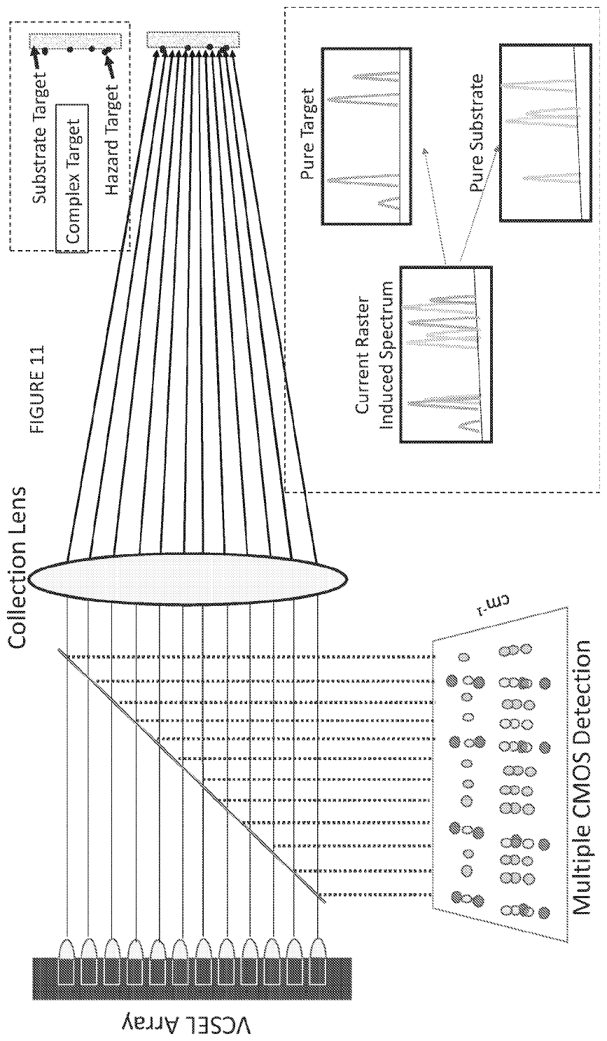

FIG. 12 shows an embodiment of a spectrometer in which Raman collection is obtained with a 2-dimensional array. In this example eight lasers provide individual excitation beams and each beam excites the sample as in FIG. 2. In this embodiment, the Raman signal from each of the eight lasers is collected along 8 rows (regions of interest) of a 2-D detector and the Raman signals are observed along the rows.

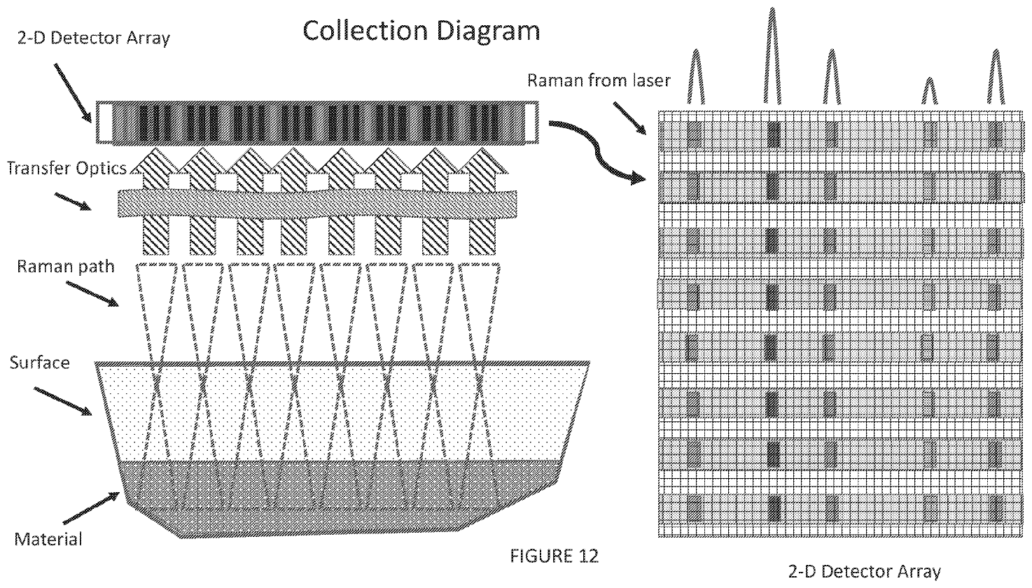

FIG. 13 shows another embodiment of a Raman spectrometer in which excitation is with a single diode laser and detection of Raman signals is performed via a linear one-dimensional (1-D) detector.

FIG. 13 illustrates the Raman collection that is possible with a laser array. With this possibility the sample may be illuminated in a relatively large area while collecting from a relatively small area that is a subset of the illuminated area. This is also shown and described with reference to FIGS. 3 and 4. One advantage is that a translucent container or barrier could transmit the illumination to a power that is highly scattering and will produce Raman in the subsurface. This approach can enhance the signal of the subsurface compared to that of the container.

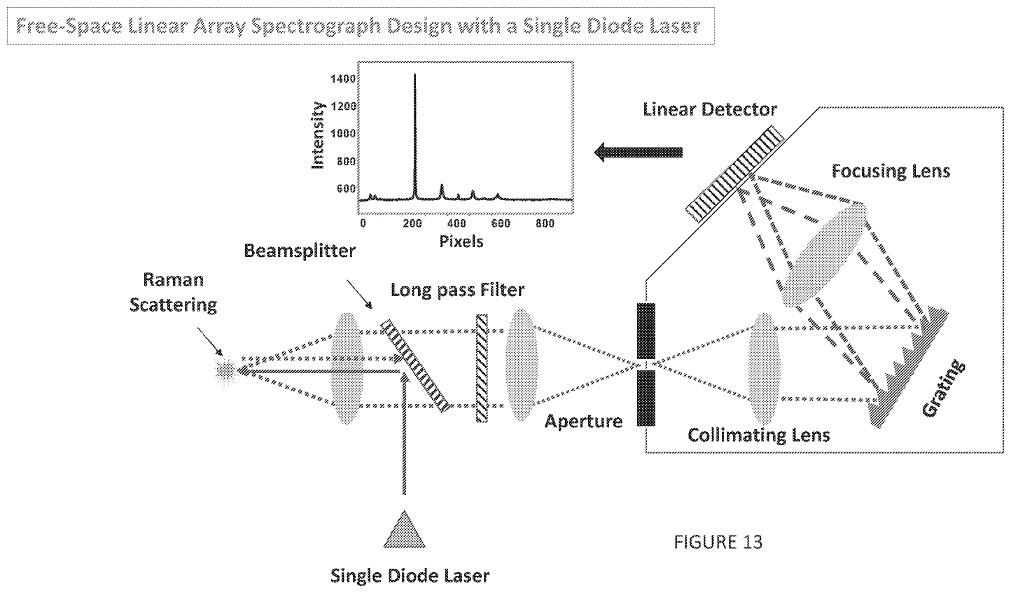

FIG. 14 shows another embodiment in which a standoff excitation is provided. In this embodiment, a fixed focus standoff comprises a Raman excitation laser, and at least one visible sighting laser (in this embodiment a pair of visible sighting lasers). The focus can be identified by a user by aligning the visible sighting lasers with the target.

FIG. 14 illustrates a mode of operation which used the crossing point of two visible laser beams to define the focal point of a fixed focus standoff Raman system. In this mode the operator may start an acquisition when the beams align. This can be difficult when two hands maybe be needed to hold a system and the acquisition button must be pressed precisely when the beams align.

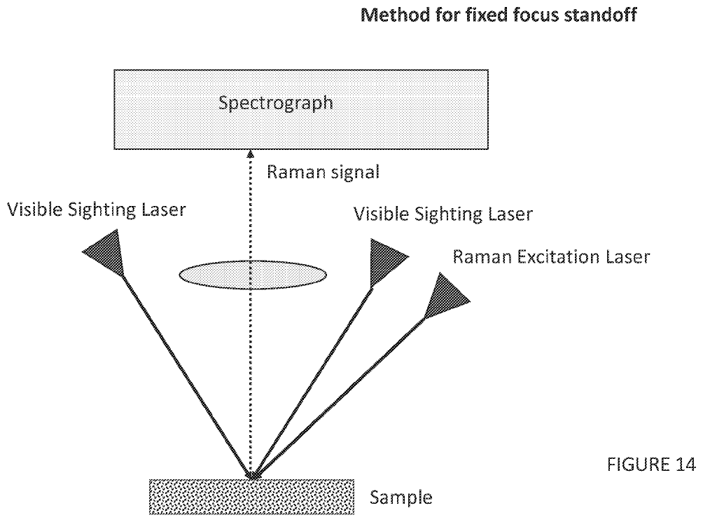

FIG. 15 shows a method of automatically triggering a sample in a fixed focus standoff spectrometer (e.g., Raman spectrometer). In this embodiment, a photodiode detector receives reflected signals from the visible sighting laser(s), and when the spectrometer is focused the photodiode (or other detector) detects the signal and illuminates a Raman excitation laser to generate a spectroscopy signal for analysis. In the embodiment shown in FIG. 15, for example, the visible laser signal is reflected along a detection axis of the spectrometer when the spectrometer is focused on the sample. The visible laser signal is reflected away from the optical detection portion of the spectrometer by a dichroic beam splitter and directed to a detector, such as the photodiode shown. In one embodiment, for example, the photodiode detects the signal and provides a leading edge or other signal indicating the spectrometer is focused on the sample and initiates a spectroscopy sample by illuminating the Raman excitation laser.

The embodiment shown in FIG. 15 provides an improved solution to a fixed standoff system. In this case one beam is crossed with the laser excitation beam. A dichroic beamsplitter is used to direct the visible laser beam to a photodiode which produces a trigger to automatically start an acquisition.

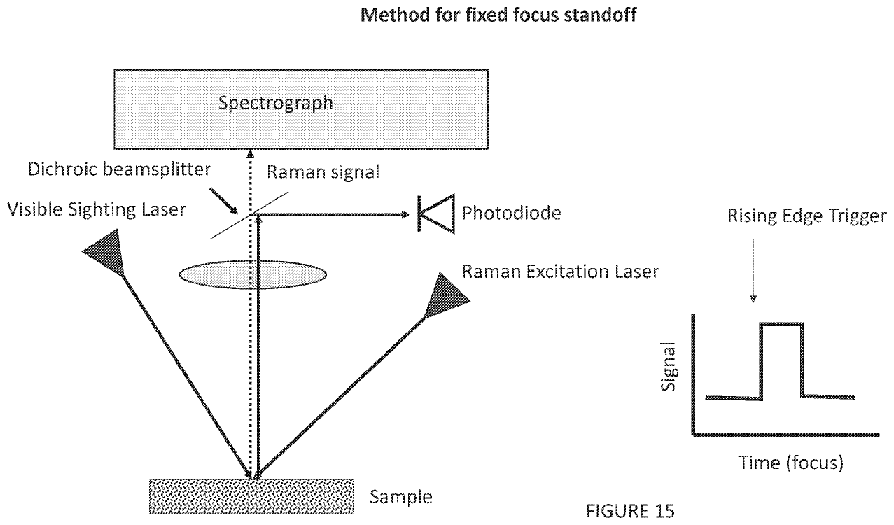

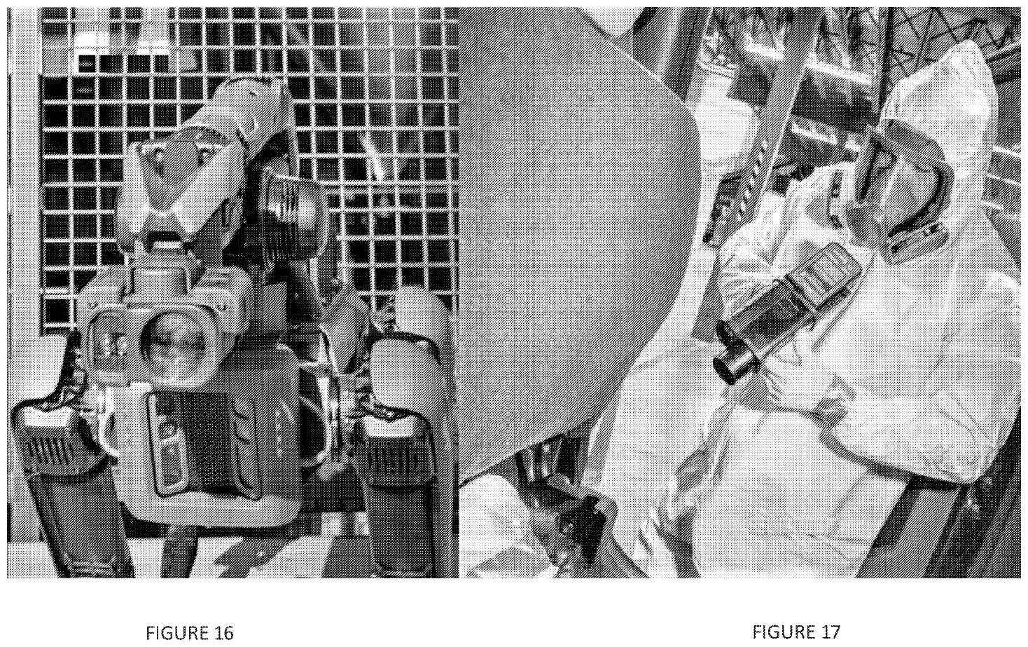

FIGS. 16 and 17 include diagrams of an example spectrometer and of the spectrometer in use.

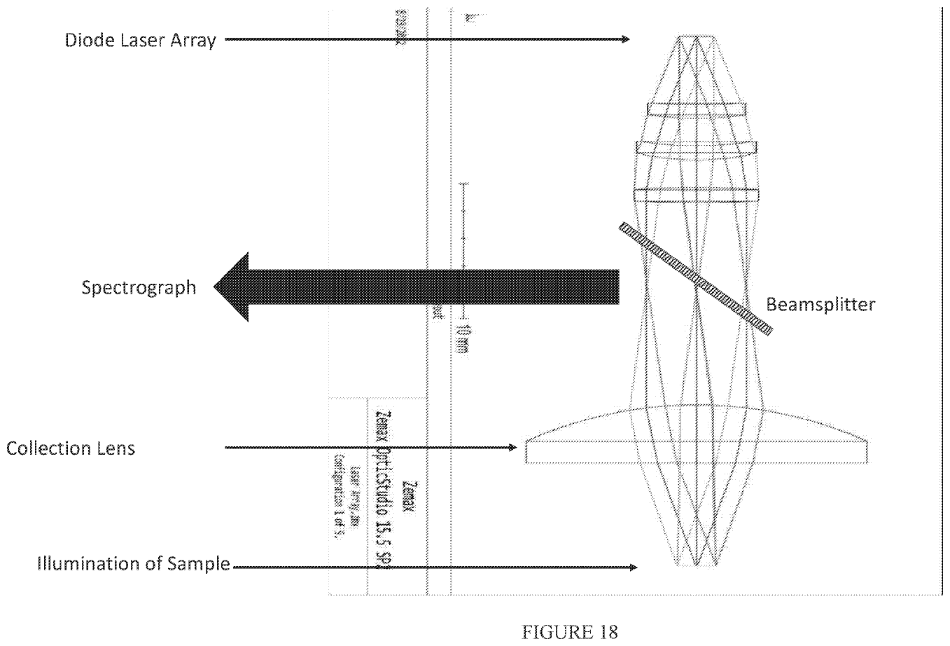

FIG. 18 is an illustration of an embodiment of optics for a laser array (e.g., VCSEL or diode laser array) imaging onto a 2-D array detector. In this embodiment, for example, the individual lasers lead to individual spatial location on the surface and that can be mapped back to a location of the detector. In this embodiment, the purity of the spatial pattern can be scaled up or down, but it does not become scrambled.

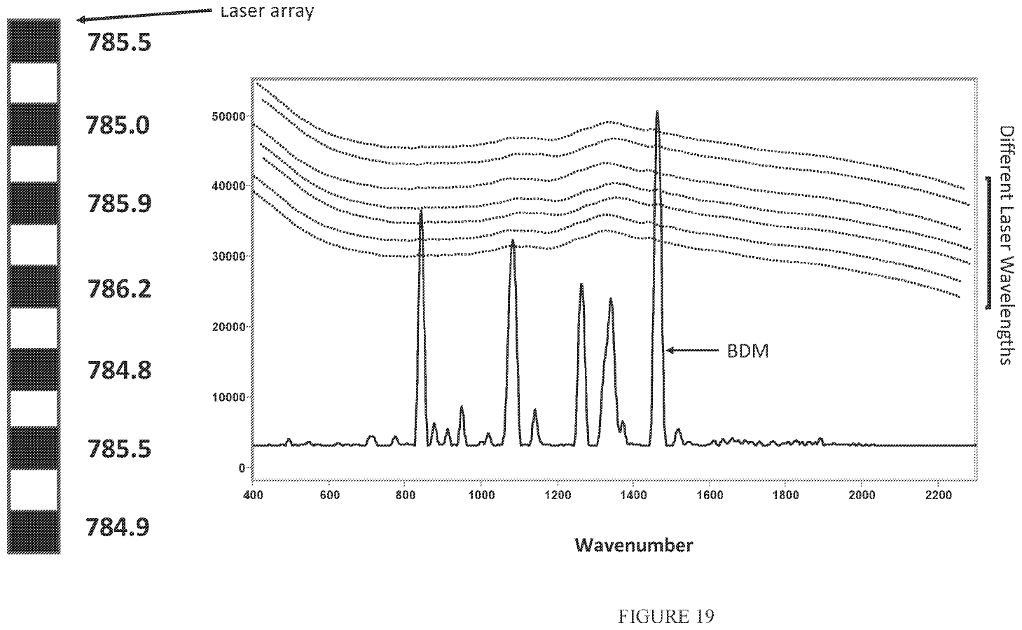

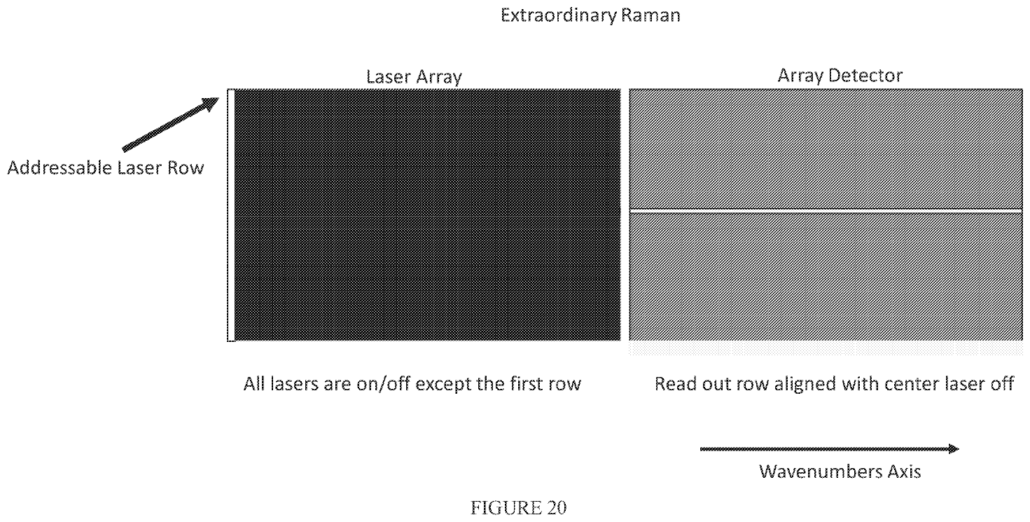

FIG. 19 illustrates an embodiment of a Raman spectrometer system comprising a combination of a laser array and a 2-D detector. The laser array may be composed of VCSEL lasers that emit narrow frequencies of light, but which may, depending on manufacturing characteristics emit at unique individual wavelengths. In other words, they may be a set of lasers each with narrow frequency operation, but within the set of lasers they may vary in wavelength. This is illustrated in the left-hand side of the FIG. 20, which shows an example in which one or more subsets of the laser array are controllable. For example, individual lasers, rows of lasers, and/or columns of lasers may be individually controllable. In the example of FIG. 20, for example, all lasers may be on or off with an exception of a first addressable row of the lasers that is controlled to be off or on, respectively.

Due to the spatial purity produced by optics as shown in FIG. 19, the Raman from these lasers will be produced on the array as individual spectra with offset Raman features due to the variation in the wavelengths. The result is a set of Raman spectra collected simultaneously (in parallel) with slightly offset Raman features.

This set of data is known for its ability to be decomposed into data sets that move and those which do not. For the application of Raman spectroscopy that means that the slow or unchanging fluorescence background can be separated from the rapidly changing Raman peaks.

FIG. 20 shows an example of a spectroscopy collection using an addressable two-dimensional laser array and an addressable two-dimensional array detector. In one embodiment, for example, a plurality of lasers in the 2-D laser array are on and the remaining lasers in the 2-D laser array are off. For example, a single addressable row of the laser array can be ON or OFF and the remaining lasers in the array can be OFF or ON, respectively. A read out of the detector can be similarly made along a first plurality of detectors of the 2-D array detector. For example, a single row aligned with a center laser of the laser array turned OFF.

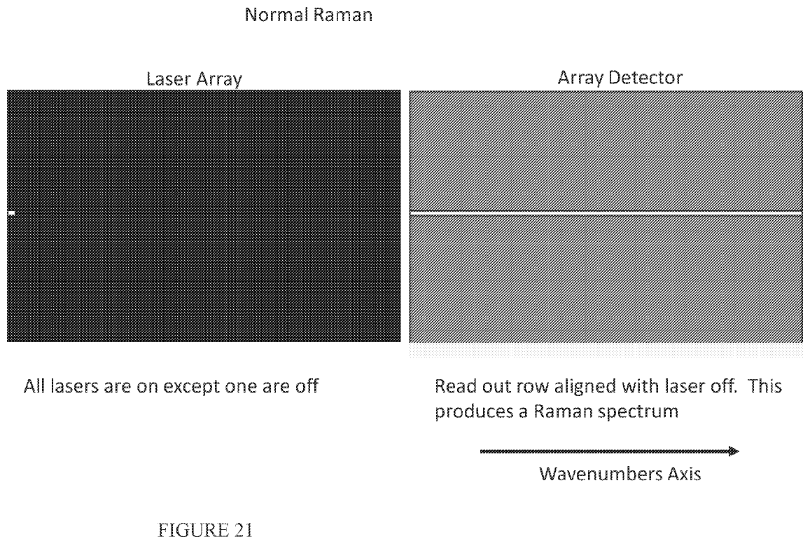

FIG. 21 shows another example of a spectroscopy collection method using an addressable 2-D laser array and an addressable 2-D array detector. In one embodiment, for example, all lasers except one may be OFF (or ON), and a read out of a row of the detector array is performed along a row aligned with a laser OFF to produce a Raman spectrum.

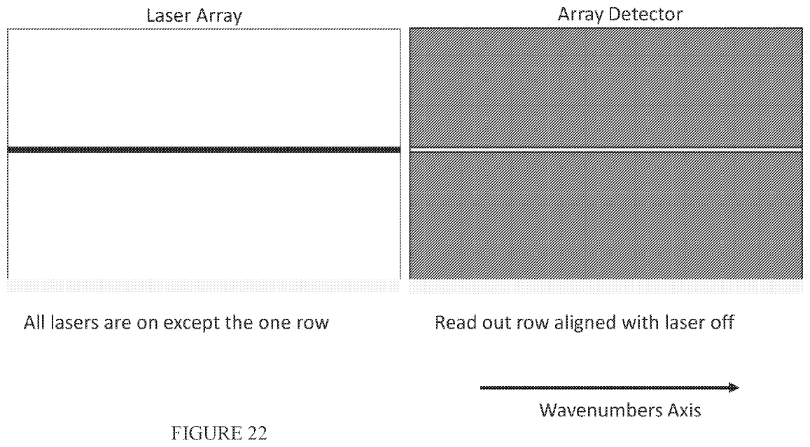

FIG. 22 shows another example of a spectroscopy collection method using an addressable 2-D laser array and an addressable 2-D array detector. In one embodiment, for example, all lasers in the 2-D laser array are ON except for one row that is OFF, and a read out of a row of the detector array is performed along a row aligned with the row of the laser array that is OFF.

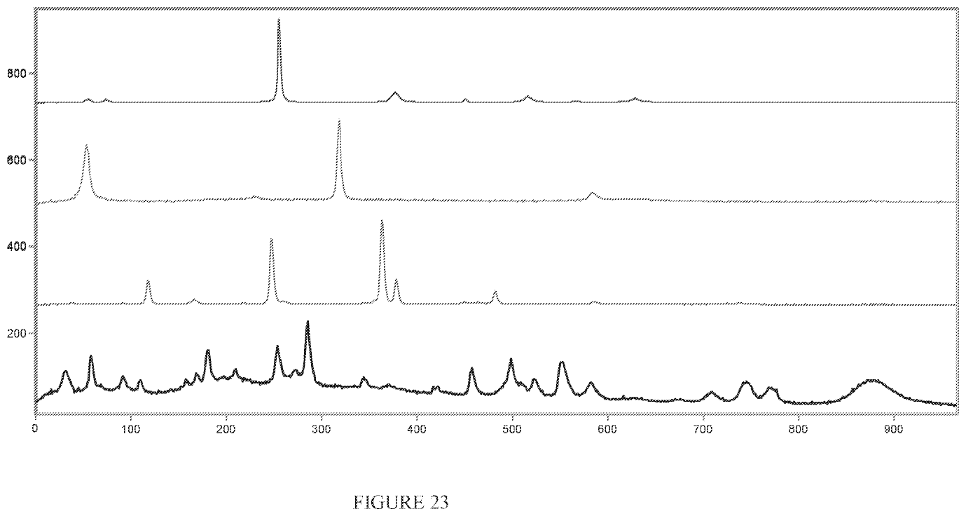

FIG. 23 shows an example of fluorescence removal through BDM (Background decomposition method).

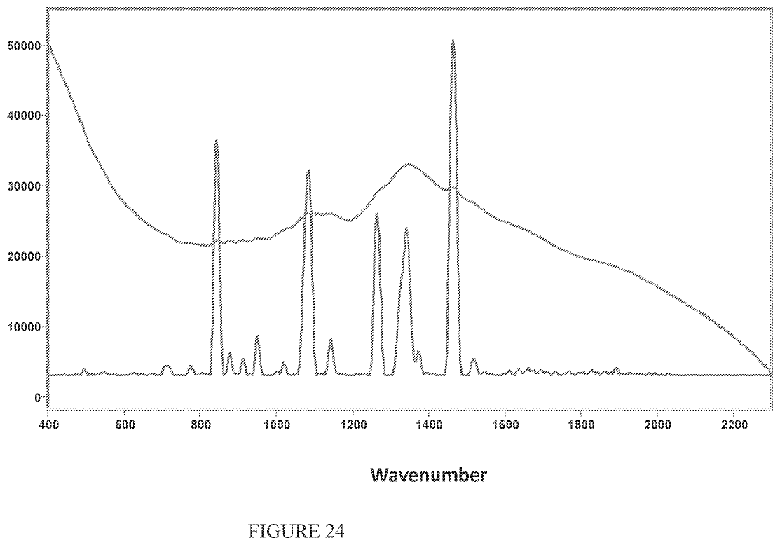

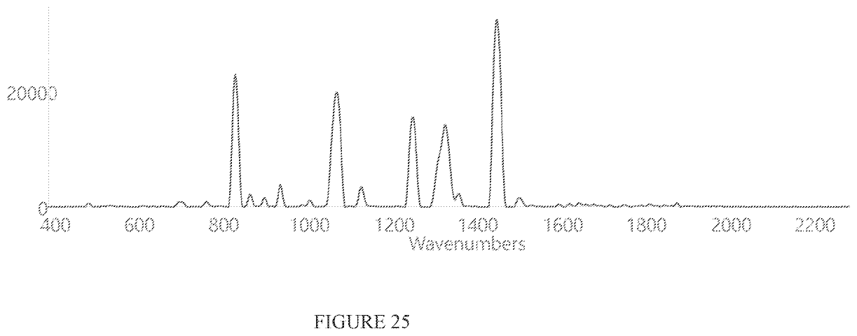

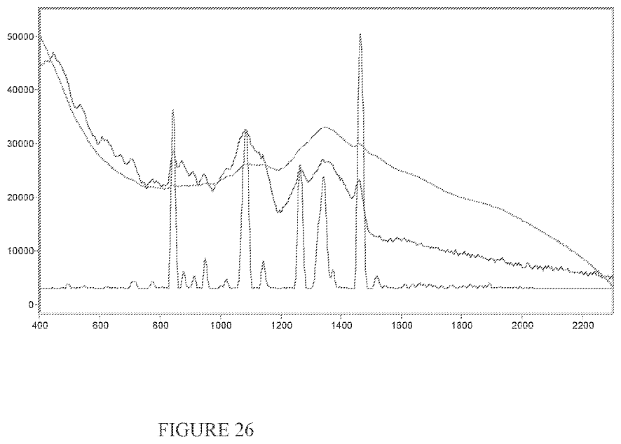

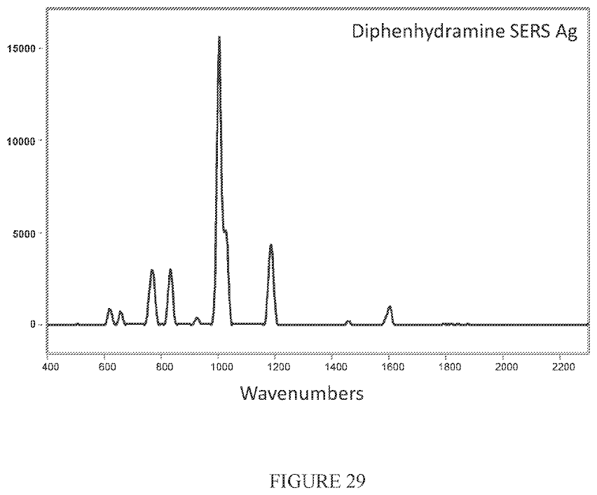

FIGS. 24-27 and 29 show example spectroscopy signals.

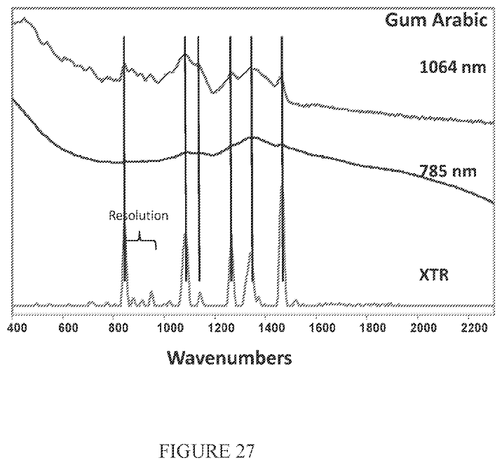

FIG. 27 shows an example of the generation of a Raman spectroscopic signal at a sample using 1064 nm and 785 nm excitation sources. In this example a method of fluorescence removal is illustrated resulting in better performance with 785 BDM over 1064 nm excitation.

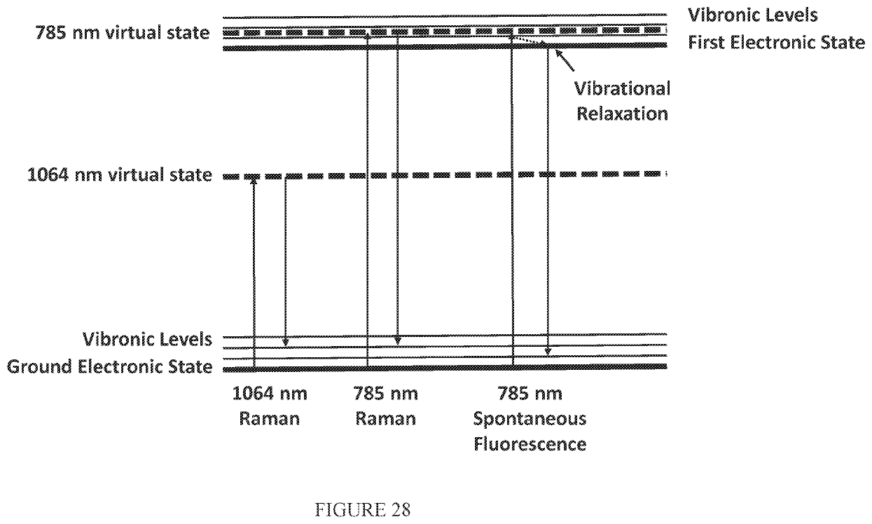

FIG. 28 illustrates the origin of the fluorescence in a Raman spectrometer application. The small arrow described as vibrational relaxation means that fluorescence is independent of the excitation wavelength and the while Raman, which is instantaneous, will shift with the laser wavelength. This difference leads to a mathematical basis for separation of fluorescence and Raman.

### Hadamard Transformation to Extract Raman Spectrum

In one embodiment, a Raman spectrum may be extracted from a complex sample using a mathematical operation such as a Hadamard transformation. In this embodiment, the idea is to recreate the entire sample illumination with Hadamard patterns the produce different spatial components from the excitation laser pixel. This will produce differential Raman signal from each pattern that correlates to different spatial distances from the single pixel excitation.

One example of a transformation is described in Zibang Zhang, Xueying Wang, Guoan Zheng, and Jingang Zhong, “Hadamard single-pixel imaging versus Fourier single-pixel imaging,” Optics Express, Vol. 25, NO. 16 19619-19639, Aug. 7, 2017, which is incorporated herein in its entirety as if fully set forth herein.

HIS (Hadamard Single-pixel Imaging) is based on Hadamard transform. HSI acquires the Hadamard spectrum of the object image and reconstructs the object image by applying an inverse Hadamard transform. Hadamard spectrum is composed by a group of Hadamard coefficients. Each coefficient corresponds to a unique Hadamard basis pattern. To obtain a Hadamard coefficient, one can project the corresponding ladamard basis pattern(s) onto the object and use a single-pixel detector to measure the resultant light intensity. The single-pixel light intensity measurement is mathematically equivalent to the inner product between the Hadamard basis pattern(s) and the object. As such, the Hadamard spectrum can be reconstructed based on the single-pixel measurements. The two-dimensional Hadamard transform H{ }H{ } of an image I(x,y)I(x,y) is defined as

$$\tilde{I} H ( u , v ) = H \{ I ( x , y ) \} = \sum x = 0 M - 1 \sum y = 0 N - 1 I ( x , y ) ( - 1 ) q ( x , y , u , v ) , {I}^{\sim} H ( u , v ) = H \{ I ( x , y ) \} = \sum x = 0 M - 1 \sum y = 0 N - 1 I ( x , y ) ( - 1 ) q ( x , y , u , v ) , \qquad ( 1 )$$

(x,y)(x,y) is the coordinate in the spatial domain

$$q ( x , y , u , v ) ≡ \sum i = 0 n - 1 [ gi ( u ) xi + gi ( v ) yi ] , q ( x , y , u , v ) ≡ \sum i = 0 n - 1 [ gi ( u ) xi + gi ( v ) yi ] , \qquad ( 2 )$$

where (u,u)(u,v) is the coordinate in the Hadamard domain, n=log 2Nn=log 2N, and

$$g 0 ( u ) ≡ un - 1 g 1 ( u ) ≡ un - 1 + un - 2 g 2 ( u ) ≡ un - 2 + un - 3. ⋮ gn - 1 ( u ) ≡ u 1 + u 0 g 0 ( u ) ≡ un - 1 g 1 ( u ) ≡ un - 1 + un - 2 g 2 ( u ) ≡ un - 2 + un - 3. ⋮gn - 1 ( u ) ≡ u 1 + u 0 \qquad ( 3 )$$

The terms uiui, vivi, xixi, and yiyi are the binary representations of uu, vv, xx, and yy respectively. For example,

$$( u ) decimal = ( un - 1 un - 2 ⋯ u 1 u 0 ) binary . ( u ) decimal = ( un - 1 un - 2 ⋯u 1 u 0 ) binary . \qquad ( 4 )$$

A frequency interpretation can be given to the Hadamard spectrum-along each row/column of the Hadamard spectrum the frequency is called the number of changes in sign. However, as Hadamard basis patterns are not strictly periodic, the word “sequency” is used to designate the number of sign changes [3-8]. Hadamard transform is only applicable for input images of size NN-by-NN, where NN, N/12N/12, or N/20N/20 is a power of 2.

A Hadamard basis pattern PH(x,y)PH(x,y) can be obtained by applying an inversed Hadamard transform to a delta function SH(u,v)δH(u,v),

$$PH ( x , y ) = 12 [ 1 + H - 1 \{ δ H ( u , v ) \} ] , PH ( x , y ) = 12 [ 1 + H - 1 \{ δ H ( u , v ) \} ] , \qquad ( 5 )$$

where H−1{ }H−1 { } denotes an inverse Hadamard transform and

$$δ H ( u , v ) = □□1 , 0 , u = u 0 , v = v 0 otherwise . δ H ( u , v ) = \{ 1 , u = u 0 , v = v 00 , otherwise . \qquad ( 6 )$$

The sample Hadamard basis pattern shown in FIG. 28 is derived by substituting u=5u=5 and v=5v=5 into equation (5). Thus, it has 5 sign changes each row and 5 sign changes each column.

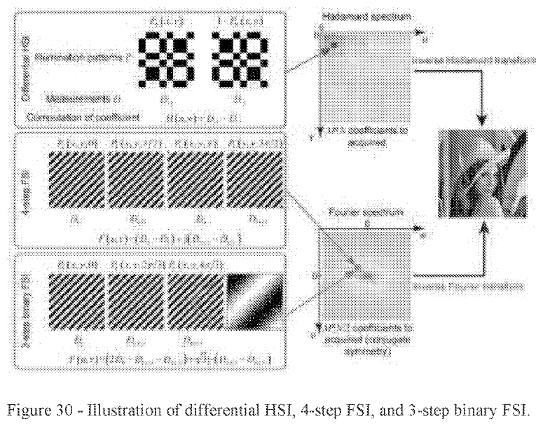

Differential HSI is an embodiment of HSI, allowing each Hadamard coefficient H(u,v)H(u,v) to be acquired in a manner of differential measurement. Differential HSI is conducive to suppression of noise. As illustrated in FIG. 30, to acquire a coefficient H(u,v)H(u,v), differential HSI takes two measurements. The one measurement is acquired by projecting a Hadamard basis pattern PH(x,y)PH(x,y) and the other measurement is by its inverse [1−PH(x,y)][1−PH(x,y)]. The coefficient H(u,v)H(u,v) is obtained by using the two corresponding measurements

$$H ( u , v ) = D + 1 - D - 1 , H ( u , v ) D + 1 - D - 1 , \qquad ( 7 )$$

where D+1D+1 and D−1D−1 are measurements corresponding to the illuminations of PH(x,y)PH(x,y) and [1−PH(x,y)][1−PI(x,y)], respectively. Hadamard coefficients are real-valued and the number of Hadamard coefficients is the same as that of image pixels. Fully sampling an N×NN×N-pixel image using differential HSI takes 2N22N2 measurements.

1. A spectrometer comprising:
a light source adapted to provide an excitation incident beam;
a detector adapted to detect a spectroscopy signal; and
an optical system adapted to direct the excitation incident beam toward a sample, receive a spectroscopy signal from the sample and provide the spectroscopy signal to the detector,
wherein the light source comprises a plurality of laser sources adapted to provide a plurality of excitation incident beams through the optical system.

2. The spectrometer of claim 1, wherein the plurality of laser sources comprises a plurality of VCSEL laser sources.

3. The spectrometer of claim 1, wherein the plurality of laser sources of the light source comprises a two-dimensional array of laser sources.

4. The spectrometer of claim 3, wherein the two-dimensional array of laser sources comprises a VCSEL laser array.

5. The spectrometer of claim 1, wherein the optical system is adapted to provide the plurality of excitation incident beams to the sample and to receive a plurality of spectroscopy signals from the sample corresponding to the plurality of excitation incident beams.

6. The spectrometer of claim 1, wherein the optical system is adapted to provide the plurality of excitation incident beams across a surface of the sample.

7. The spectrometer of claim 1, wherein at least a portion of the plurality of laser sources are addressable.

8. The spectrometer of claim 7, wherein each of the laser sources are individually addressable.

9. The spectrometer of claim 7, wherein at least two portions of the plurality of laser sources are individually addressable.

10. The spectrometer of claim 1, wherein the detector comprises a plurality of detector elements.

11. The spectrometer of claim 10, wherein the plurality of detector elements comprises a two-dimensional array of detector elements.

12. The spectrometer of claim 10, wherein at least a portion of the plurality of detector elements are addressable.

13. The spectrometer of claim 12, wherein each of the detector elements are individually addressable.

14. The spectrometer of claim 12, wherein at least two portions of the plurality of detector elements are individually addressable.

15. The spectrometer of claim 1, wherein the spectrometer comprises a controller adapted to process one or more detector signals from the detector.

16. The spectrometer of claim 15, wherein the controller is adapted to correct a curvature of the spectroscopy signal at the detector.

17. The spectrometer of claim 16, wherein the controller is adapted to correct the curvature by fitting a circle to a known line.

18. The spectrometer of claim 15, wherein the controller is adapted to linearize the detected spectroscopy signal received at the detector.

19. The spectrometer of claim 1, wherein the optical system comprises a lens adapted to flatten an intensity profile of the spectroscopy signal at the detector.

20. The spectrometer of claim 1, wherein the detector comprises a plurality of detector elements adapted to detect a plurality of spectroscopy signals corresponding to the plurality of excitation incident beams.

21. The spectrometer of claim 20, wherein the spectrometer comprises a controller adapted to separate spectra of a target material and a second material of a sample.

22. The spectrometer of claim 21, wherein the sample comprises an inhomogeneous sample.

23. The spectrometer of claim 21, wherein the second material comprises a surface of the sample.

24. The spectrometer of claim 1, wherein the optical system comprises a beam expander adapted to expand the plurality of excitation incident beams at a surface of the sample.

26. A spectrometer comprising:
a light source adapted to provide an excitation incident beam;
a detector adapted to detect a spectroscopy signal; and
an optical system adapted to direct the excitation incident beam toward a sample, receive a spectroscopy signal from the sample and provide the spectroscopy signal to the detector,
wherein the detector comprises a plurality of detector elements.

27. The spectrometer of claim 26, wherein the light source comprises a VCSEL laser source.

28. The spectrometer of claim 26, wherein the light source comprises a plurality of laser sources adapted to provide a plurality of excitation incident beams.

29. The spectrometer of claim 28, wherein the plurality of laser sources comprises a two-dimensional array of laser sources.

30. The spectrometer of claim 29, wherein the two-dimensional array of laser sources comprises a VCSEL laser array.

31. The spectrometer of claim 28, wherein the optical system is adapted to provide the plurality of excitation incident beams to the sample and to receive a plurality of spectroscopy signals from the sample corresponding to the plurality of excitation incident beams.

32. The spectrometer of claim 28, wherein the optical system is adapted to provide the plurality of excitation incident beams across a surface of the sample.

33. The spectrometer of claim 28, wherein at least a portion of the plurality of laser sources are addressable.

34. The spectrometer of claim 26, wherein the plurality of detector elements comprises a two-dimensional array of detector elements.

35. The spectrometer of claim 26, wherein at least a portion of the plurality of detector elements are addressable.

36. The spectrometer of claim 35, wherein each of the detector elements are individually addressable.

37. The spectrometer of claim 35, wherein at least two portions of the plurality of detector elements are individually addressable.

38. The spectrometer of claim 26, wherein the spectrometer comprises a controller adapted to process one or more detector signals from the detector.

39. The spectrometer of claim 38, wherein the controller is adapted to correct a curvature of the spectroscopy signal at the detector.

40. The spectrometer of claim 39, wherein the controller is adapted to correct the curvature by fitting a circle to a known line.

41. The spectrometer of claim 38, wherein the controller is adapted to linearize the detected spectroscopy signal received at the detector.

42. The spectrometer of claim 26, wherein the optical system comprises a lens adapted to flatten an intensity profile of the spectroscopy signal at the detector.

43. The spectrometer of claim 26, wherein plurality of detector elements are adapted to detect a plurality of spectroscopy signals corresponding to a plurality of excitation incident beams.

44. The spectrometer of claim 43, wherein the spectrometer comprises a controller adapted to separate spectra of a target material and a second material of a sample.

45. The spectrometer of claim 44, wherein the sample comprises an inhomogeneous sample.

46. The spectrometer of claim 44, wherein the second material comprises a surface of the sample.

47. The spectrometer of claim 26, wherein the optical system comprises a beam expander adapted to expand the plurality of excitation incident beams at a surface of the sample.

48. A spectrometer comprising:
a light source adapted to provide an excitation incident beam;
a detector adapted to detect a spectroscopy signal; and
an optical system adapted to direct the excitation incident beam toward a sample, receive a spectroscopy signal from the sample and provide the spectroscopy signal to the detector,
wherein the optical system comprises a beam expander adapted to expand the excitation incident beam.

49. A method for determining at least one spectrum of a sample, the method comprising:
providing a plurality of excitation incident beams from a light source comprising a plurality of light sources;
directing the plurality of excitation incident beams to a sample via an optical system;
receiving a spectroscopy signal from the sample via the optical system; and
directing the spectroscopy signal to a detector via the optical system;
determining at least one spectrum corresponding to the spectroscopy signal.

50. The method of claim 49, wherein the operation of determining at least one spectrum is performed via a controller.

51. A method for determining at least one spectrum of a sample, the method comprising:
providing an excitation incident beam from a light source;
directing the excitation incident beam to a sample via an optical system;
receiving a spectroscopy signal from the sample via the optical system;
directing the spectroscopy signal to a detector via the optical system, wherein the detector comprises a plurality of detector elements; and
determining at least one spectrum corresponding to the spectroscopy signal.

50. The method of claim 49, wherein the operation of determining at least one spectrum is performed via a controller.

51. The method of claim 49, wherein the detector comprises a two-dimensional array of detector elements.

52. A method for determining at least one spectrum of a sample, the method comprising:
providing an excitation incident beam from a light source;
directing the excitation incident beam to a sample via an optical system;
expanding the excitation incident beam within the optical system;
receiving a spectroscopy signal from the sample via the optical system; and
directing the spectroscopy signal to a detector via the optical system;
determining at least one spectrum corresponding to the spectroscopy signal.

53. The method of claim 52, wherein the operation of determining at least one spectrum is performed via a controller.
